(19) United States
(12) Patent Application Publication
(10) Pub. No.: US 2012/0060886 A1
(43) Pub. Date: Mar. 15, 2012

(54) HIGH TEMPERATURE FLEXIBLE ELECTRODE

(75) Inventors: William R. Determan, Sylmar, CA (US); Daniel Edward Matejczyk, West Hills, CA (US)

(73) Assignee: HAMILTON SUNDSTRAND CORPORATION, Windsor Locks, CT (US)

(21) Appl. No.: 12/879,608

(22) Filed: Sep. 10, 2010

(51) Int. Cl. H01L 35/30

(52) U.S. Cl. 136/222

(57) ABSTRACT

An electrode including a first portion to be electrically coupled to a first thermoelectric leg and mechanically coupled to a first heat collector part, a second portion to be electrically coupled to a second thermoelectric leg and mechanically coupled to a second heat collector part and a flexible portion connected between the first and second portions whereby current is transmittable between the first and second thermoelectric legs.

### FEDERAL RESEARCH STATEMENT

This invention was conceived under JPL Contract No. 1320783 with the National Air and Space Administration (NASA) having an effective date of Apr. 21, 2009 and relating to demonstration of fabrication technology.

### BACKGROUND OF THE INVENTION

The subject matter disclosed herein relates to a high temperature flexible electrode.

High temperature electrical conductors provide electrical conductivity from one thermoelectric leg to another in a thermoelectric couple. However, when the thermoelectric legs are joined by connectors having high characteristic stiffness, differing thermal expansions of the thermoelectric leg materials can cause mechanical stress that, in turn, can lead to fracture of the legs.

### BRIEF DESCRIPTION OF THE INVENTION

According to an aspect of the invention, an electrode is provided and includes a first portion to be electrically coupled to a first thermoelectric leg and mechanically coupled to a first heat collector part, a second portion to be electrically coupled to a second thermoelectric leg and mechanically coupled to a second heat collector part and a flexible portion connected between the first and second portions whereby current is transmittable between the first and second thermoelectric legs.

According to another aspect of the invention, an electrode is provided and includes a first planar portion to be electrically coupled to a first thermoelectric leg and mechanically coupled to a first heat collector part, a second planar portion to be electrically coupled to a second thermoelectric leg and mechanically coupled to a second heat collector part and a flexible substantially omega-shaped portion electrically interposed between the first and second portions whereby current is transmittable between the first and second thermoelectric legs.

According to yet another aspect of the invention, a thermoelectric couple is provided and includes a heat collector having first and second parts, first and second electrical leads, mechanically coupled to and electrically insulated from one another, first and second thermoelectric legs electrically coupled to the first and second electrical leads, respectively, and an electrode including a first portion electrically coupled to the first thermoelectric leg and mechanically coupled to the first heat collector part, a second portion electrically coupled to the second thermoelectric leg and mechanically coupled to the second heat collector part and a flexible portion connected between the first and second portions.

These and other advantages and features will become more apparent from the following description taken in conjunction with the drawings.

### BRIEF DESCRIPTION OF THE DRAWING

The subject matter which is regarded as the invention is particularly pointed out and distinctly claimed in the claims at the conclusion of the specification. The foregoing and other features, and advantages of the invention are apparent from the following detailed description taken in conjunction with the accompanying drawings in which:

FIG. 1 is a perspective view of a high temperature flexible electrode incorporated into a thermoelectric couple; and

FIG. 2 is a perspective view of an electrode of the high temperature flexible electrode assembly of FIG. 1.

The detailed description explains embodiments of the invention, together with advantages and features, by way of example with reference to the drawings.

### DETAILED DESCRIPTION OF THE INVENTION

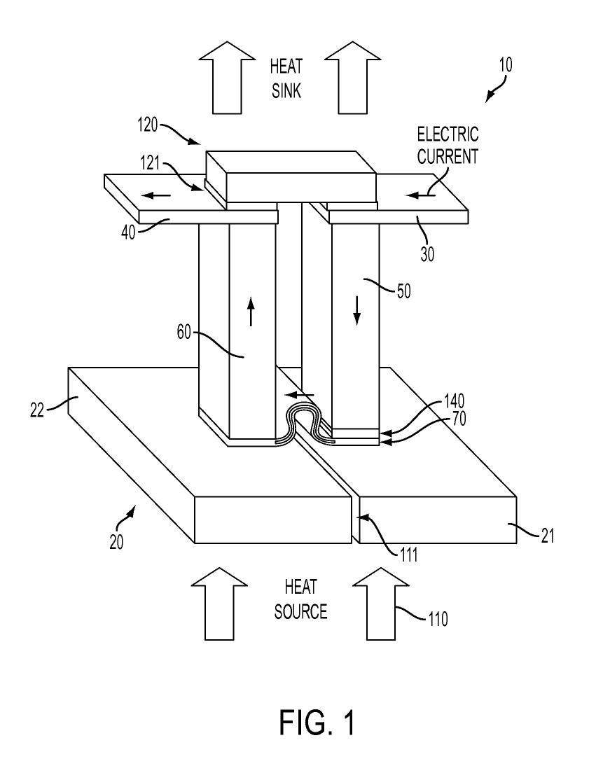

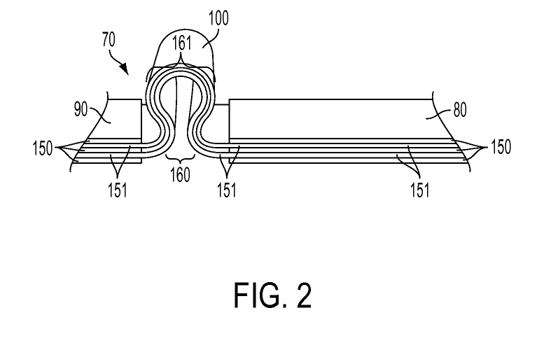

High temperature flexible electrical conductors provide electrical conductivity through a flexible structure that limits mechanical forces applied by one thermoelectric leg on the other leg. When this force must be limited due to a low stress allowance in one of the thermoelectric legs, an interconnecting strap can be constructed as a multi-layered strap to allow for a flexible structure with low electrical loss. If the interconnect distance between electrical leads is quite small, these straps can be configured into an omega-shaped multi-layered strap similar to the structure shown in FIGS. 1 and 2.

With reference to FIGS. 1 and 2, a thermoelectric couple 10 is provided and includes a heat collector 20 having a first heat collector part 21 and a second heat collector part 22, a first electrical lead 30 and a second electrical lead 40, which are mechanically coupled to and electrically insulated from one another, a first thermoelectric leg 50 electrically coupled to the first electrical lead 30 and a second thermoelectric leg 60 electrically coupled to the second electrical lead 40, and an electrode 70. As shown in FIG. 2, the electrode 70 includes a first portion 80 electrically coupled to the first thermoelectric leg 50 and mechanically coupled to the first heat collector part 21, a second portion 90 electrically coupled to the second thermoelectric leg 60 and mechanically coupled to the second heat collector part 22 and a flexible portion 100 electrically interposed and connected between the first and second portions 80 and 90.

A heat source may be disposed in contact with surfaces of the heat collector 20 and a heat sink may be provided to remove heat from the heat source. As such, a predominant direction of heat flow is defined through the thermoelectric couple 10 along heat flow pathway 110, which extends from the heat collector 20 to the electrode 70 and so forth. The first heat collector part 21 and the second heat collector part 22 are separated from one another along a border 111.

The thermoelectric couple 10 further includes a radiator attachment 120 and electrical insulators 121. The radiator attachment 120 is mechanically coupled to each of the first and second thermoelectric legs 30 and 40. The electrical insulators 121 are electrically interposed between each of the first and second thermoelectric legs 30 and 40 and the radiator attachment 120. The first and second electrical leads 30 and 40 each include copper or a similar electrically conductive material. When connected in an electric circuit, current flows in series through the first electrical lead 30, the first thermoelectric material 50, the electrode 70, the second thermoelectric material 60 and to the second electrical lead 40.

The first thermoelectric leg 50 may include a p-type thermoelectric material. By contrast, the second thermoelectric leg 60 may include an n-type thermoelectric material. Further, the first thermoelectric leg 50 and the first portion 80 of the electrode 70 may have different cross-sectional dimensions as compared to the second thermoelectric leg 60 and the second portion of the electrode 90 for optimum generation of electric power.

The thermoelectric couple 10 may further include an optional thermal expansion compensator 140. When used, the thermal expansion compensator 140 is electrically interposed between one of the thermoelectric legs 50 or 60 and the first portion 80 or the second portion 90 of the electrode 70, respectively. In this way, heat from the heat source that causes the electrode 70 to thermally expand and contract may be additionally compensated for so that the connections between the first and second thermoelectric materials 50, 60 and the electrode 70 may be maintained.

The high temperature flexible electrode may be fabricated of Molybdenum (Mo) alloy or a similar material having sufficient electrical conductivity, stability at elevated temperature, and compatibility with adjacent materials.

As shown in FIGS. 1 and 2, a cross-section of the flexible portion 100 of the electrode 70 is substantially omega-shaped. That is, the flexible portion 100 of the electrode 70 includes a narrow neck section 160, which is proximate to the heat collector 20, and a bulbous section 161 connected to the neck section 160.

As shown in FIG. 2, the flexible section is composed of two thin sheets separated by an open space. Also as shown in FIG. 2, one or both of the first portion 80 or the second portion 90 of the electrode 70 may include three layers of, for example, Molybdenum 151 or 150, joined by diffusion bonding, to provide a method of fabricating the desired geometry. Fabrication is accomplished by, first, machining the desired shape for the flexible portion of the electrode 70 via electrical discharge machining and, second, completing the first and/or the second portions 80 and 90 by diffusion bonding in an additional sheet section of Molybdenum alloy or another suitable metal 150 to close gaps therein.

The thermoelectric couple 10 in general and the electrode 70 in particular can accommodate relative vertical motion between the first and second thermoelectric legs 50, 60 and limit the mechanical load imparted from one to the other in a relatively short separation distance between the first and second electrical leads 30, 40. The geometry of the flexible portion 100 of the electrode 70 enables a significant reduction, by a factor of possibly more than 100 times in bending moments imparted from one electrical lead 30, 40 to the other when they become vertically displaced.

While Molybdenum alloy was used to fabricate the high-temperature flexible electrode 70 for a 1,000° C. vacuum environment, it is to be understood that different materials could be substituted for lower operating temperature regimes with gaseous environments. The unique feature of the omega-shaped flexible portion 100 decreases interconnecting distance while allowing for electrode 70 length to also decrease the bending moments imparted from one electrical lead to the other and also decreases a voltage drop through the flexible portion 100.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. An electrode, comprising:
a first portion to be electrically coupled to a first thermoelectric leg and mechanically coupled to a first heat collector part;
a second portion to be electrically coupled to a second thermoelectric leg and mechanically coupled to a second heat collector part; and
a flexible portion connected between the first and second portions whereby current is transmittable between the first and second thermoelectric legs.

2. The electrode according to claim 1, wherein the first and second portions are substantially flat and substantially planar.

3. The electrode according to claim 1, wherein one or both of the first and second portions comprise layers of similar or dissimilar materials that are diffusion bonded together during fabrication.

4. The electrode according to claim 3, wherein one or both of the first and second portions comprise 3 layers of diffusion bonded material.

5. The electrode according to claim 1, comprising Molybdenum (Mo) alloy.

6. The electrode according to claim 1, wherein a cross-section of the flexible portion is substantially omega-shaped.

7. An electrode, comprising:
a first planar portion to be electrically coupled to a first thermoelectric leg and mechanically coupled to a first heat collector part;
a second planar portion to be electrically coupled to a second thermoelectric leg and mechanically coupled to a second heat collector part; and
a flexible substantially omega-shaped portion electrically interposed between the first and second portions whereby current is transmittable between the first and second thermoelectric materials.

8. The electrode according to claim 7, comprising Molybdenum (Mo) alloy.

9. A thermoelectric couple, comprising:
a heat collector having first and second parts;
first and second electrical leads, mechanically coupled to and electrically insulated from one another;
first and second thermoelectric legs electrically coupled to the first and second electrical leads, respectively; and
an electrode including a first portion electrically coupled to the first thermoelectric leg and mechanically coupled to the first heat collector part, a second portion electrically coupled to the second thermoelectric and mechanically coupled to the second heat collector part and a flexible portion connected between the first and second portions.

10. The thermoelectric couple according to claim 9, further comprising:
a radiator attachment mechanically coupled to each of the first and second electrical leads; and
insulation electrically interposed between each of the first and second electrical leads and the radiator attachment.

11. The thermoelectric couple according to claim 9, wherein the first and second electrical leads each comprise copper.

12. The thermoelectric couple according to claim 9, wherein the first thermoelectric leg comprises a p-type thermoelectric material.

13. The thermoelectric couple according to claim 9, wherein the second thermoelectric leg comprises an n-type thermoelectric material.

14. The thermoelectric couple according to claim 9, wherein the first thermoelectric leg and the first portion of the electrode have different cross-sectional dimensions than the second thermoelectric leg and the second portion of the electrode.

15. The thermoelectric couple according to claim 9, further comprising:
a thermal expansion compensator electrically interposed between one of the thermoelectric legs and one of the portions of the electrode.

16. The thermoelectric couple according to claim 9, wherein the electrode comprises layers of diffusion bonded material.

17. The thermoelectric couple according to claim 16, wherein the electrode comprises 3 layers of material.

18. The thermoelectric couple according to claim 9, wherein the flexible portion comprises Molybdenum (Mo) alloy.

19. The thermoelectric couple according to claim 9, wherein a cross-section of the flexible portion of the electrode is substantially omega-shaped.

20. The thermoelectric couple according to claim 9, wherein the flexible portion of the electrode comprises a narrow neck section proximate to the heat collector and a bulbous section connected to the neck section.
